(19) United States
(12) Patent Application Publication
(10) Pub. No.: US 2026/0363076 A1
(43) Pub. Date: Nov. 12, 2026

(54) DYNAMIC LIQUID COOLING FOR INTEGRATED DEVICE

(71) Applicant: Taiwan Semiconductor Manufacturing Company, Ltd., Hsinchu (TW)

(72) Inventors: Kuan-Min Wang, Hsinchu City (TW); Chien-Chang Wang, Hsinchu City (TW); Bang-Li Wu, Hsinchu City (TW); Kuo-Chin Chang, Chiayi City (TW); Kathy Wei Yan, Hsinchu (TW); Jun He, Zhubei City (TW)

(21) Appl. No.: 19/735,621

(22) Filed: Jul. 9, 2026

Related U.S. Application Data
(62) Division of application No. 18/659,470, filed on May 9, 2024.

(51) Int. Cl. H10W 40/47; H05K 7/20; H10W 40/77

(52) U.S. Cl. CPC H10W 40/475; H05K 7/20254; H05K 7/20281; H05K 7/20518; H10W 40/776; H05K 2201/064

(57) ABSTRACT

Some embodiments relate to an integrated circuit cooling system including: an impingement coolant block overlying a semiconductor die; an inlet opening in the impingement coolant block and coupled to an inlet; a plurality of tubes extending in a first direction directly beneath the inlet opening and having first ends and second ends, where the plurality of tubes are respectively centered on first axes; a plurality of valves coupling the first ends of the plurality of tubes to the inlet opening; a plurality of impingement openings within the impingement coolant block and respectively surrounding the second ends of the second plurality of tubes, where the plurality of impingement openings are respectively centered on the first axes; and an outlet opening within the impingement coolant block and between the inlet opening and the plurality of impingement openings, the outlet opening physically coupling the plurality of impingement openings to an outlet.

### REFERENCE TO RELATED APPLICATION

This Application is a Divisional of U.S. Application number 18/659,470, filed on May 9, 2024, the contents of which are hereby incorporated by reference in their entirety.

### BACKGROUND

In integrated circuits, inefficiencies and resistance within semiconductor devices results in some energy being released as thermal energy. A buildup of thermal energy within an integrated circuit may lead to increased resistances and power requirements, a shifting of threshold voltages for transistor operation, and potentially failure of the circuit components. Various methods of cooling integrated devices have been developed over the years, including utilizing heat spreaders, fans, and liquid cooling systems to take thermal energy away from the integrated device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, and 1F illustrate cross-sectional views and top down views of some embodiments of a liquid cooling system with a plurality of openings directing a coolant at specific regions of a semiconductor die.

FIGS. 2A, 2B, 2C, and 2D illustrate top-down views of some embodiments of a liquid cooling system with a plurality of openings directing a coolant at specific regions of a semiconductor die, where a higher volume of the plurality of openings are positioned over a hot spot of the semiconductor die.

FIGS. 3A, 3B, 3C, and 3D illustrate top-down views of some embodiments of a liquid cooling system with a plurality of openings directing a coolant at specific regions of a semiconductor die, where a higher volume of the plurality of openings are positioned over multiple hot spots of the semiconductor die.

FIGS. 4A, 4B, 4C, 4D,and 4E illustrate top-down views and a cross-sectional view of some embodiments of a liquid cooling system with a plurality of openings directing a coolant at specific regions of a plurality of semiconductor dies, where a higher volume of the plurality of openings are positioned over hot spots of the plurality of semiconductor dies.

FIGS. 5, 6, 7A, 7B, 8-12, 13A, 13B, 14A, and 14B illustrate a series of cross-sectional views of some embodiments of a method of forming a liquid cooling system with a plurality of openings directing a coolant at specific regions of a semiconductor die using a plurality of valves.

FIG. 15 illustrates a flowchart of some embodiments of a method of forming a liquid cooling system with a plurality of openings directing a coolant at specific regions of a semiconductor die using a plurality of valves.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A liquid cooling structure comprises an inlet and an outlet. Liquid cooling structures are positioned on or near integrated devices in order to more effectively transfer heat away from the integrated device. Conventional liquid cooling structures operate by passing a coolant liquid from the inlet to the outlet across a surface of the integrated device. Excess heat from the integrated device is transferred to the coolant liquid before it is passed out of the outlet and away from the integrated device, transferring the excess heat away. While a design where the coolant travels directly between the inlet and the outlet is simple to produce, coolant traveling across a surface is less effective at transferring heat than coolant directly impinging on a surface, resulting in the most effective heat transfer only occurring directly beneath the inlet. In some embodiments, a heat spreader is disposed between the integrated device and the liquid cooling structure, to further distribute the excess heat away from the integrated device.

As semiconductor manufacturing technology improves, semiconductor devices utilizing the new technology are frequently formed closer together to reduce the form factor, lower size limitations, and increase manufacturing yield. New technologies also may have lower tolerances for excess thermal energy, and thermal energy may build up faster in smaller areas. In some embodiments, conventional liquid cooling structures may be inadequate for controlling the temperature of active areas of the integrated device that are not directly beneath the inlet, as the flow of coolant across the surface is less effective for heat transfer than the coolant directly impinging on the surface beneath the inlet. Further, the coolant system described above has a static path for the coolant, and may deliver coolant to inactive areas that are not overheating. In some embodiments, an integrated device may have a variety of regions that are active and generate thermal energy at different times during operation, where a conventional liquid cooling structure may not fully mitigate the effects of the excess thermal energy generated in dynamically changing active regions of the integrated device. Therefore, a liquid cooling structure that may dynamically adjust liquid flow volume and directly impinge on specific regions of the integrated circuit is desirable.

The present disclosure provides for a liquid cooling structure that comprises a plurality of impingement openings and a plurality of valves that dynamically adjust coolant flow volume to the plurality of impingement openings. The plurality of impingement openings are distributed across an upper surface of the integrated device. The plurality of valves are actuated to direct the liquid coolant to flow towards and impinge on specific openings of the plurality of openings that are over an active region of the integrated device. Excess heat from the overheating region is transferred to the impinging liquid, reducing the excess heat within the integrated device. The liquid coolant is then removed from the impingement openings, transferring the excess heat away from the overheating region.

During operation, the number of valves actuated above the overheating region may be informed by the amount of excess heat within the overheating region. This may be based on measuring the heat in the integrated device, or may be a state based operation that informs which regions of the integrated device may be active. As the number and location of actuated valves and the flow volume of the liquid coolant may be determined dynamically during operation, overheating regions of the integrated devices may be cooled as determined by a controller. Further, a coolant liquid directly impinging on a surface is more effective at transferring thermal energy out of the surface than the same coolant liquid flowing across the surface, resulting in a more effective cooling system. Dynamically responding to specific overheating regions with liquid coolant directly impinging on the overheating regions with an adjustable volume results in a greater amount of control and effectiveness in cooling integrated devices.

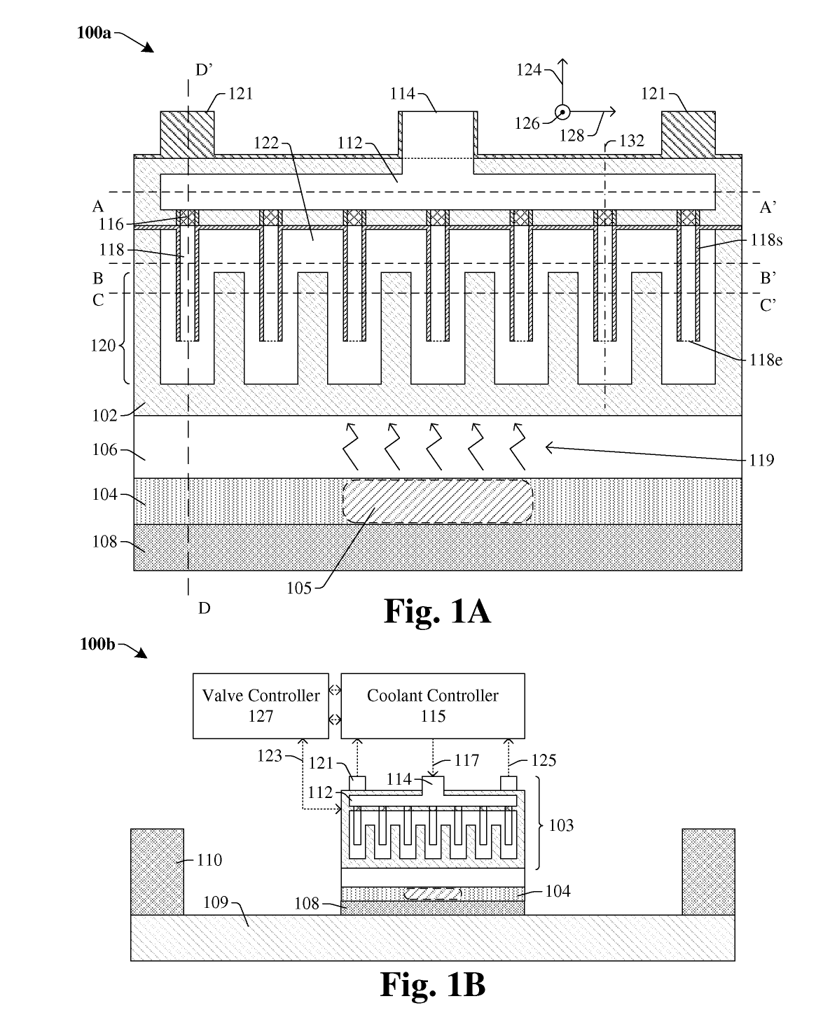

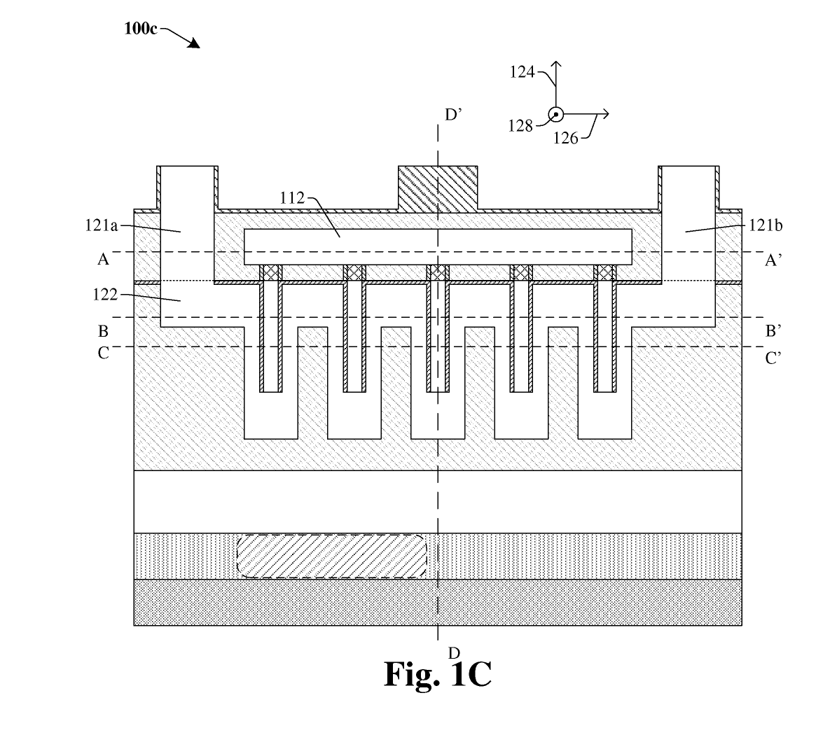

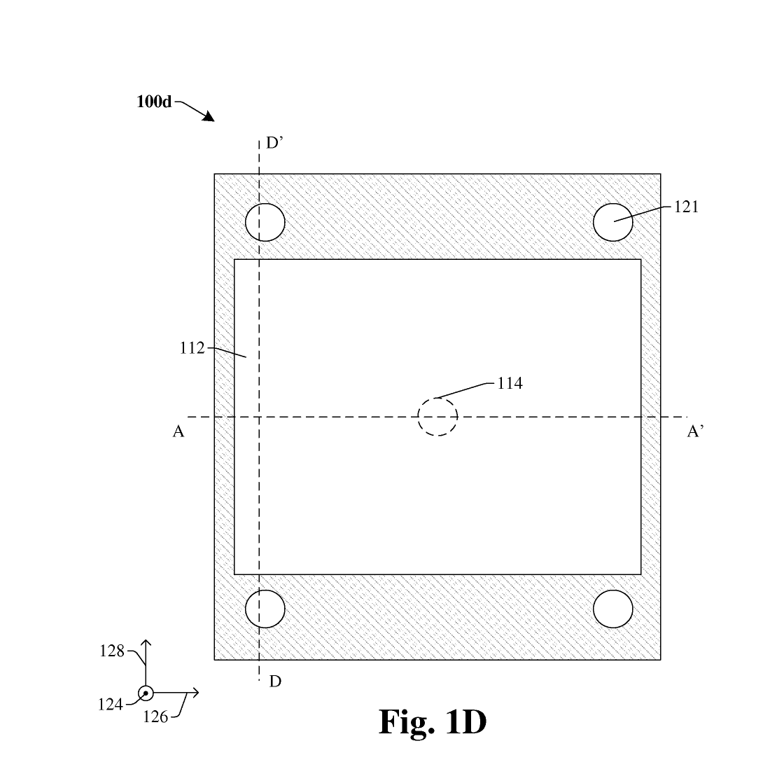

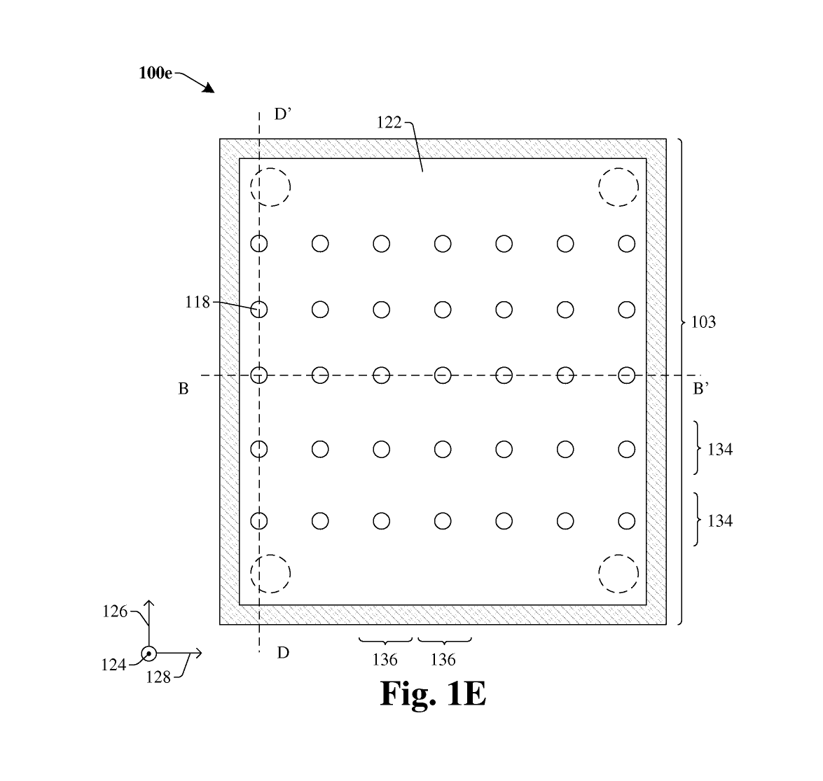

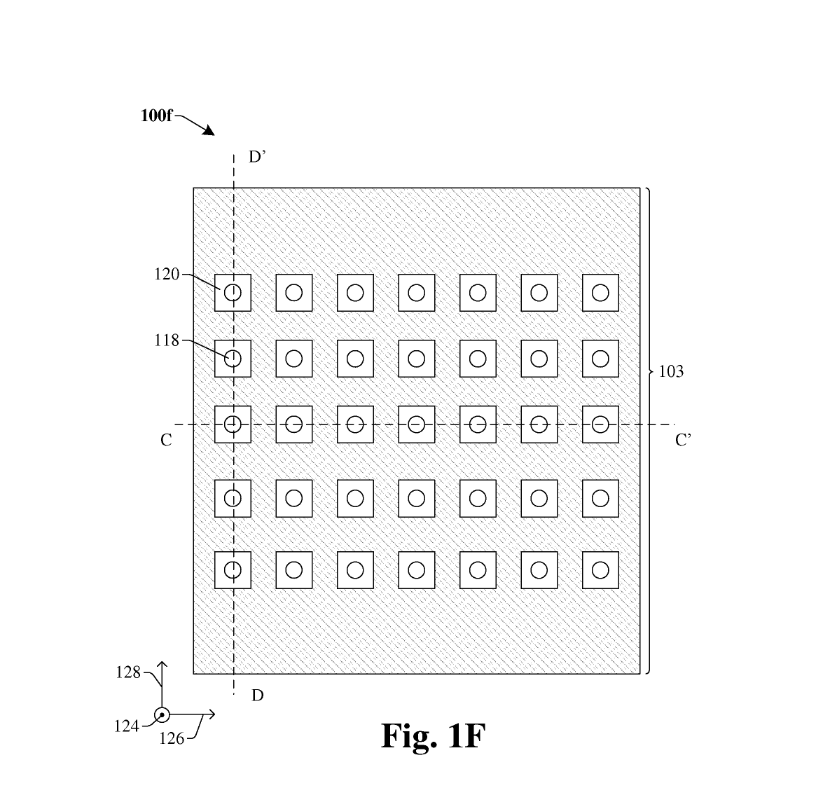

FIGS. 1A, 1B, 1C, 1D, 1E, and 1F illustrate cross-sectional views 100a, 100b, 100c and top down views 100d, 100e, 100f of some embodiments of a liquid cooling system with a plurality of openings directing a coolant at specific regions of a semiconductor die. The cross-sectional view 100c of FIG. 1C is taken along the line D-D’ of FIG. 1A (see D-D’ also in FIGS. 1D, 1E, and 1F). The top down view 100d of FIG. 1D is taken along line A-A’ of FIG. 1A. The top down view 100e of FIG. 1E is taken along line B-B’ of FIG. 1A. The top down view 100f of FIG. 1F is taken along line C-C’ of FIG. 1A. FIGS. 1A and 1B are described concurrently.

As shown in the cross-sectional views 100a, 100b of FIGS. 1A and 1B, an impingement cooling block 103 overlies a first semiconductor die 104 in a first direction 124. The impingement cooling block 103 comprises a coolant containment structure 102 that is separated from the first semiconductor die 104 by a thermal interface material 106. In some embodiments, the first semiconductor die 104 is separated from a substrate 109 by an underfill layer 108. In some embodiments, stiffeners 110 extend from the substrate 109 and surround the first semiconductor die 104 to reduce damage that may be caused by impacts or falls.

The impingement cooling block 103 further comprises an inlet opening 112 at the top of the impingement cooling block 103. The inlet opening 112 is coupled to an inlet 114. The inlet 114 is coupled to a coolant controller 115 by a first coolant line 117. During operation, the coolant controller 115 directs coolant into the inlet opening 112. A plurality of valves 116 line a bottom surface of the inlet opening 112. The plurality of valves 116 are distributed along the bottom surface of the inlet opening 112 in a second direction 126 perpendicular to the first direction 124 and a third direction 128 perpendicular to both the first direction 124 and the second direction 126. The plurality of valves respectively separate the inlet opening 112 from a plurality of tubes 118. In some embodiments, a first wire level 123 is embedded into the coolant containment structure 102 and comprises a plurality of wires to couple the plurality of valves 116 to a valve controller 127. In some embodiments, the valve controller 127 is an integrated circuit that is coupled to and communicates with the coolant controller 115 to coordinate the flow volume and number of impingement openings 120 in use.

The plurality of tubes 118 comprise inner sidewalls 118s that extend to tube ends 118e that couple the inside of the plurality of tubes 118 to a plurality of impingement openings 120. The plurality of impingement openings 120 are distributed across a lower region of the impingement cooling block 103, and surround the tube ends 118e of the plurality of tubes 118. In some embodiments, the plurality of tubes 118 extend along central axes 132 in a first direction 124, and the plurality of impingement openings 120 are concentric with the plurality of tubes 118. That is, the plurality of impingement openings 120 have second central axes that coincide with the positions of the central axes 132. The plurality of impingement openings 120 are coupled on one side to an outlet opening 122. The outlet opening 122 overlies the plurality of impingement openings 120 and is coupled to one or more outlets 121. The one or more outlets 121 couple the outlet opening 122 to second coolant lines 125, which are further coupled to the coolant controller 115.

During operation, the plurality of tubes 118 direct the coolant towards a plurality of impingement openings 120 in a lower region of the impingement cooling block 103. Thermal energy 119 resulting from the operation of the first semiconductor die 104 is conducted through the thermal interface material 106 to the impingement cooling block 103. The thermal energy 119 is then transferred to the coolant impinging on the impingement cooling block 103 in the plurality of impingement openings 120. The continued flow of the coolant through the impingement cooling block 103 pushes the coolant in the plurality of impingement openings 120 into the outlet opening 122 and through to the one or more outlets 121. The one or more outlets then direct the coolant to the second coolant lines 125, where the coolant returns to the coolant controller 115. In some embodiments, the coolant comprises one or more of water, silicon oil, mineral oil, fluorine liquid, dielectric liquid, or the like.

In some embodiments, during operation, the first semiconductor die has one or more active regions 105. Active regions 105 are regions of the first semiconductor die 104 that contain a plurality of circuit components that are transmitting or transforming electric signals. Resistance in the circuit components result in the release of thermal energy into the first semiconductor die 104. The buildup of thermal energy increases the temperature in the first semiconductor die 104, which may result in increased inefficiency and potential failure of the circuit components. During operation, the plurality of valves 116 of the impingement cooling block 103 are actuated to regulate the temperature of the first semiconductor die. The plurality of valves 116 are used to control the volume of coolant that is directed at the active regions 105 by controlling the number of open valves.

Further, in some embodiments, different regions of the first semiconductor die 104 may become part of the one or more active regions 105. For example, the first semiconductor die 104 may have multiple circuits that fulfill different functions and that are active at different times. The plurality of valves 116 may be controlled to direct the coolant at the current active regions 105 while stopping the flow of coolant to other regions that are not in danger of overheating. The dynamic control of the flow volume and greater precision in the direction of coolant towards active regions 105 of the first semiconductor die 104 results in a more efficient and effective impingement cooling block 103. Further, as the coolant is directly impinging on a region of the impingement cooling block 103 directly above the active regions 105 instead of flowing across the region, the effectiveness of the heat transfer is increased, further increasing the effectiveness of the impingement cooling block 103.

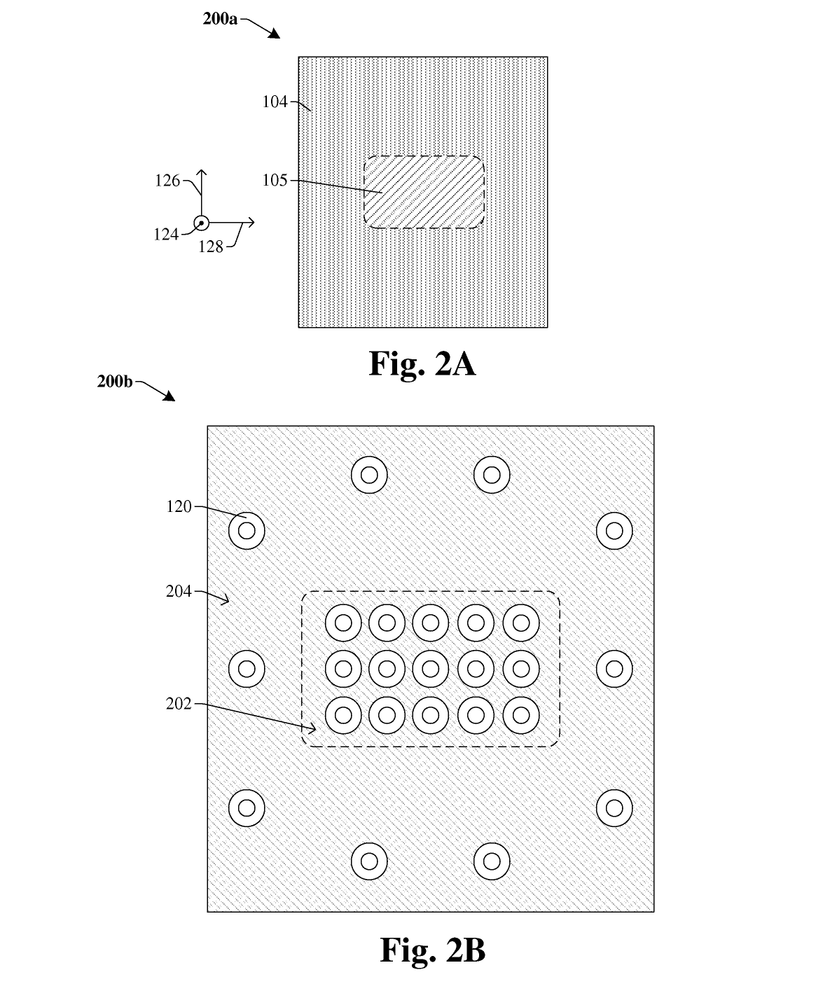

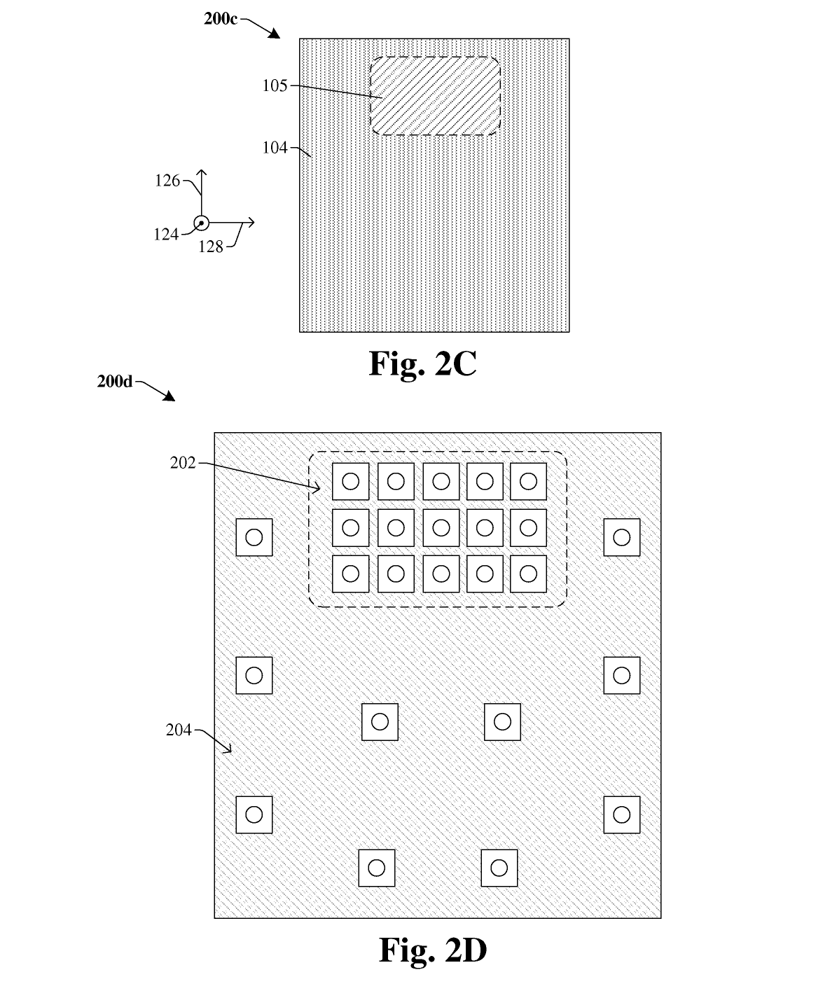

As shown in the cross-sectional view 100c of FIG. 1C, the outlet opening 122 has outermost sidewalls that extend past outermost sidewalls of the inlet opening 112 in the second direction 126. The inlet opening 112 is directly between a first outlet 121a and a second outlet 121b of the outlets 121. As shown in the top down view 100dof FIG. 1D, in some embodiments, there are four outlets 121 spaced around the outer edge of the inlet opening 112. In some embodiments, the inlet 114 (shown in phantom) is directly above the center of the inlet opening 112. As shown in the top down view 100eof FIG. 1E, in some embodiments, the plurality of tubes 118 are evenly distributed in a grid pattern across the impingement cooling block 103. That is, in some embodiments, the plurality of tubes 118 are organized into a plurality of rows 134 extending in a third direction 128 and a plurality of columns 136 extending in a second direction 126. As shown in the top down view 100f of FIG. 1F, in some embodiments, the plurality of impingement openings 120 have square cross-sections when viewed from a top down perspective. In other embodiments (see FIG. 2B), the plurality of impingement openings 120 have circular cross-sections when viewed from a top-down perspective. The plurality of impingement openings 120 extend across the impingement cooling block 103 in a same pattern as the plurality of tubes 118.

FIGS. 2A, 2B, 2C, AND 2D illustrate top-down views of some embodiments of a liquid cooling system with a plurality of openings directing a coolant at specific regions of a semiconductor die, where a higher volume of the plurality of openings are positioned over a hot spot of the semiconductor die. FIGS. 2A and 2C are cross-sectional views of the first semiconductor die 104 and show the location of the active regions 105 that are present in some embodiments. FIGS. 2B and 2D show some embodiments of the distribution of the plurality of impingement openings 120 corresponding to the location of the active regions 105 of FIGS. 2A and 2C.

As shown in the top down view 200a of FIG. 2A, in some embodiments, the first semiconductor die 104 has the active region 105 centered on the first semiconductor die 104 in the second direction 126 and the third direction 128. In some embodiments, the active region 105 has a greater concentration of circuit components in the area of the active region compared to concentration of circuit components in regions surrounding the active region 105. In other embodiments, the active region 105 is defined by a greater concentration of high power devices than the concentration of high power devices in the regions surrounding the active region 105. High power devices are integrated circuit components that utilize a greater voltage and current in their functioning than other devices, such as a high voltage transistor array compared to a low voltage transistor array. The higher voltage and current utilized by the high power devices may result in a greater amount of thermal energy generated. In some embodiments, the active region 105 comprises a power management circuit, one or more processors, a central processing unit, a graphics processing unit, or the like. In further embodiments, regions surrounding the active region 105 may comprise memory arrays, control systems, logic circuits, or the like.

In some embodiments, the positions of the active regions 105 (e.g., the regions that release larger amounts of thermal energy during operation) may be determined through testing or analysis of the die layout. In other embodiments, the position of the active region 105 may be sensed by thermal sensors coupled to the valve controller (see 127 of FIG. 1B) during operation, may be programmed into the valve controller (see 127 of FIG. 1B) before operation, or may be determined based on logical signals received by the valve controller (see 127 of FIG. 1B).

As shown in the top down view 200b of FIG. 2B, in some embodiments, the plurality of impingement openings 120 are distributed to have a higher concentration of impingement openings 120 in a first region 202 directly above the active region 105 than a second region 204 not directly above the active region 105. As shown in FIG. 2B, in some embodiments, the plurality of impingement openings 120 have circular cross-sections when view from a top down perspective. The embodiments represented in FIG. 2B has a lower number of impingement openings 120 than the embodiments represented in FIG. 1F. As the plurality of impingement openings 120 respectively surround tubes of the plurality of tubes 118 that are coupled to the plurality of valves (see 116 of FIG. 1A), a lower amount of impingement openings 120 reduces the number of electronic components in the impingement cooling block 103 while maintaining control of the flow volume of coolant over the active region 105. The reduction in the number of electronic components reduces the number of points of failure in the impingement cooling block 103, resulting in an increased lifetime of the device.

As shown in the top down view 200c of FIG. 2C, in some embodiments, the first semiconductor die 104 has the active region 105 offset from the center of the first semiconductor die 104 in one or both of the second direction 126 and the third direction 128. As shown in the cross-sectional view 200d of FIG. 2D, in some embodiments, the first region 202 with the higher concentration of impingement openings 120 is offset from the center of the first semiconductor die (see 104 of FIG. 2C) in the second direction 126 and the third direction 128 by the same amount as the active region (see 105 of FIG. 2C).

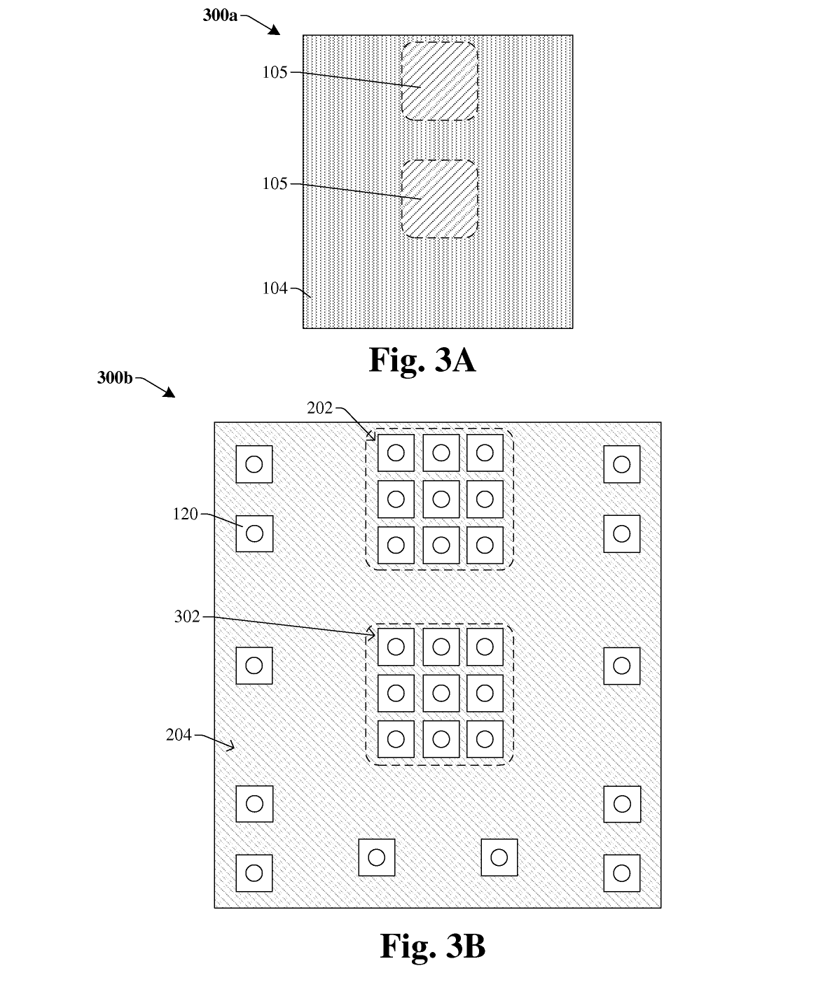

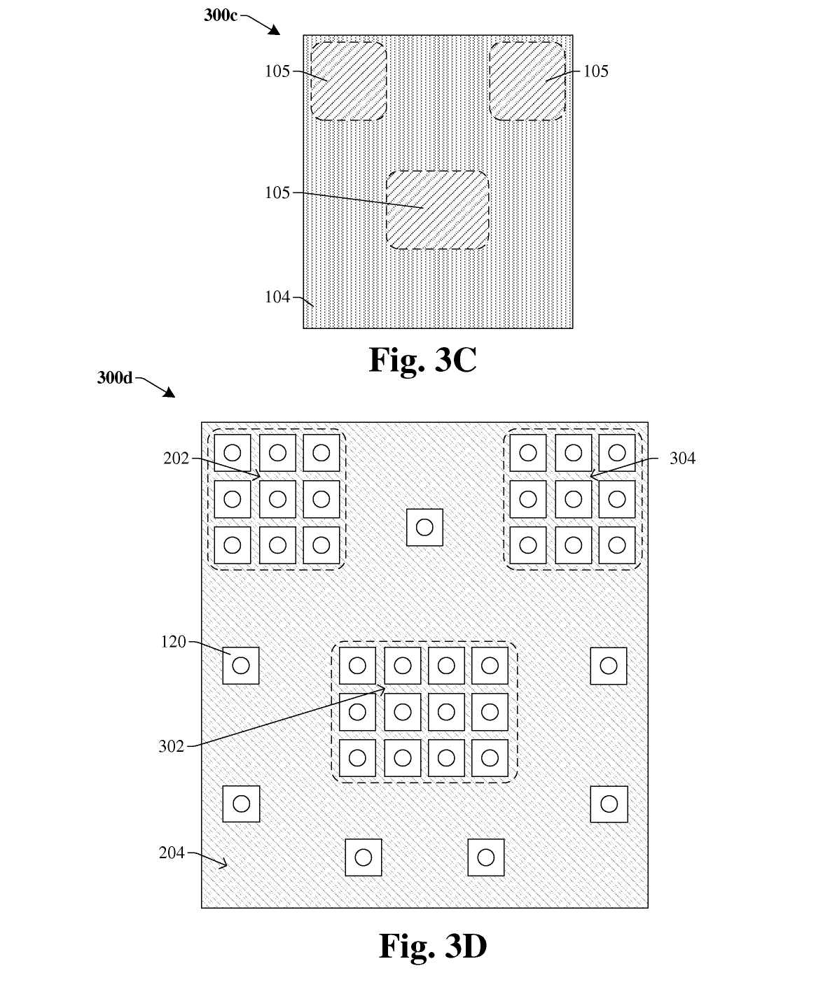

FIGS. 3A, 3B, 3C, 3D illustrate top down views 300a, 300b, 300c, 300d of some embodiments of a liquid cooling system with a plurality of impingement openings directing a coolant at specific regions of a semiconductor die, where a higher volume of the plurality of impingement openings are positioned over multiple hot spots of the semiconductor die. FIGS. 3A and 3C are cross-sectional views of the first semiconductor die 104 and show the location of the active regions 105 that are present in some embodiments. FIGS. 3B and 3D show some embodiments of the distribution of the plurality of impingement openings 120 corresponding to the location of the active regions 105 of FIGS. 3A and 3C.

As shown in the top down views 300a, 300c of FIGS. 3A and 3C, in some embodiments there are multiple active regions 105 spaced from one another. In further embodiments, the multiple active regions 105 are not always active at the same time, as the circuits contained within them may perform different functions. As shown in the top down view 300bof FIG. 3B, in some embodiments with two active regions 105, there are the first region 202 and a third region 302 with a higher volume per unit area of impingement openings 120 than the second region 204. As shown in the top down view 300d of FIG. 3D, in some embodiments with three active regions 105, there are the first region 202, the third region 302, and a fourth region 304 with a higher volume per unit area of impingement openings 120 than the second region 204. In other embodiments, the impingement openings 120 may be distributed in a grid pattern across the first semiconductor die 104, with the valve controller (see 127 of FIG. 1B) configured to actuate the valves over the active regions 105.

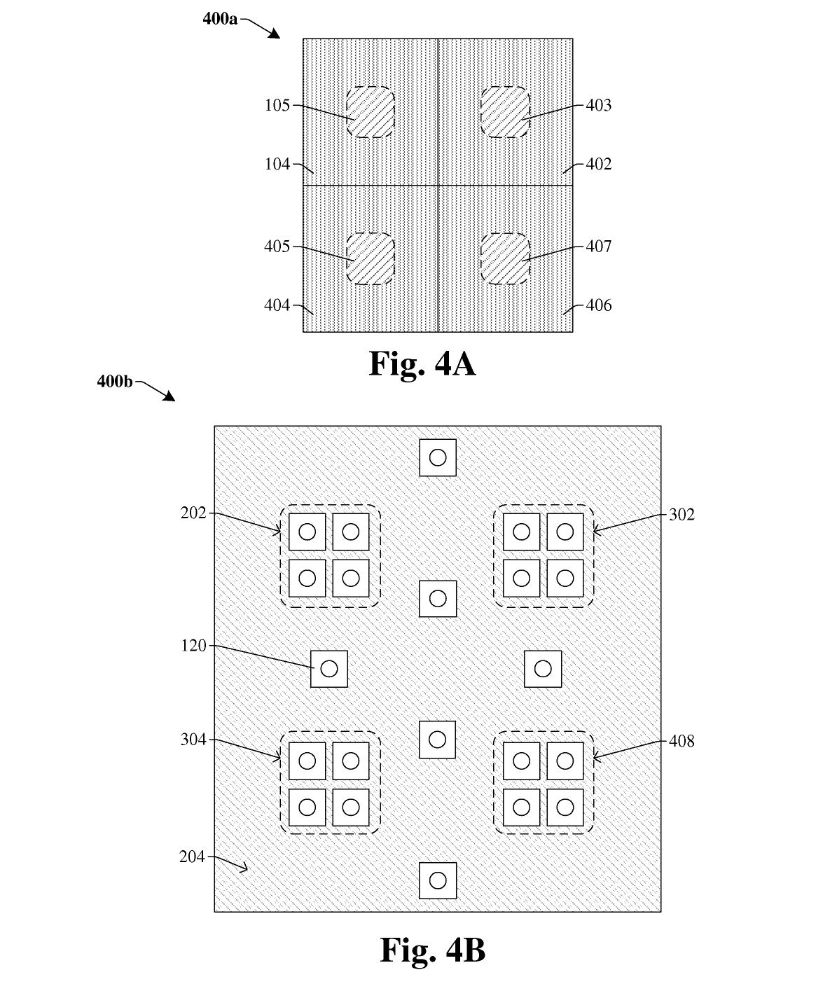

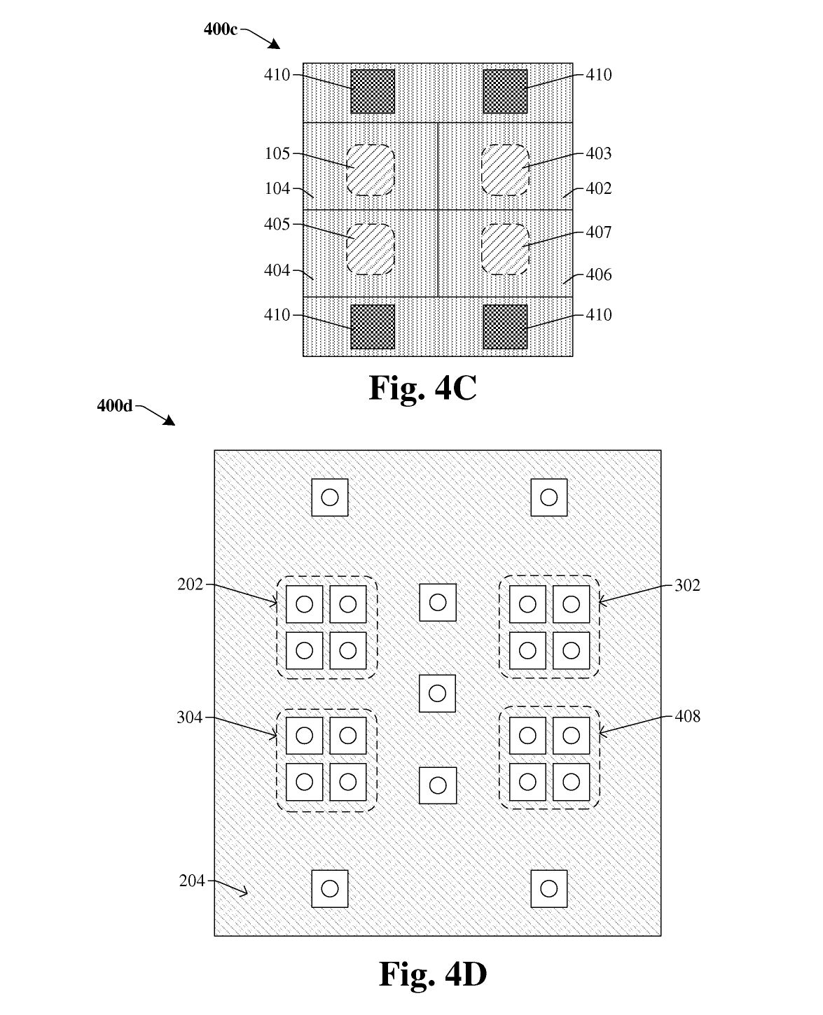

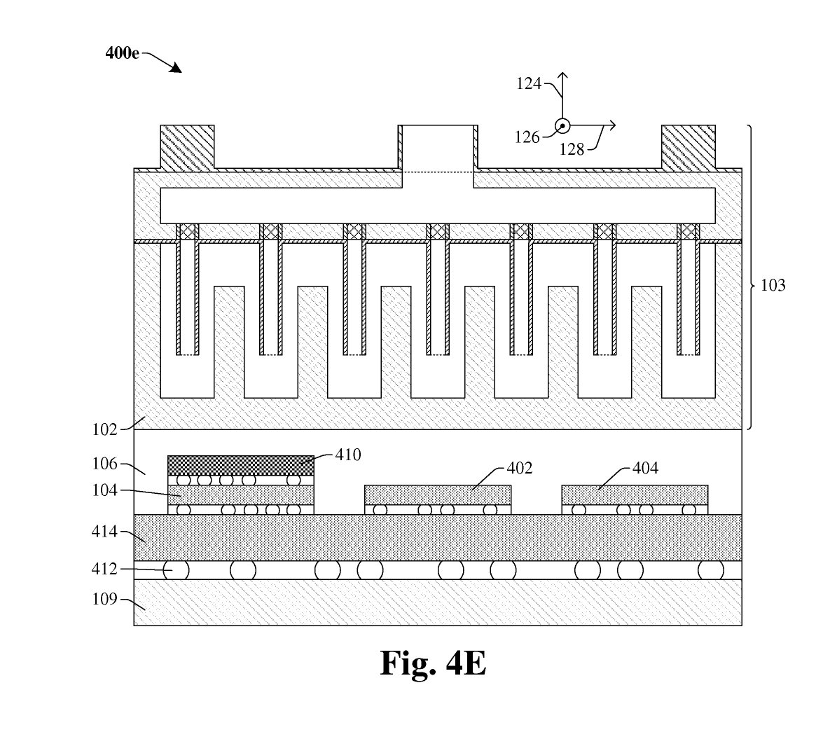

FIGS. 4A, 4B, 4C, 4D, and 4E illustrate top down views 400a, 400b, 400c, 400d and a cross-sectional view 400e of some embodiments of a liquid cooling system with a plurality of openings directing a coolant at specific regions of a plurality of semiconductor dies, where a higher volume of the plurality of openings are positioned over hot spots of the plurality of semiconductor dies.

As shown in the top down view 400a of FIG. 4A, in some embodiments, the first semiconductor die 104, a second semiconductor die 402, a third semiconductor die 404, and a fourth semiconductor die 406 are positioned directly beneath the impingement cooling block 103. In other embodiments, a different number of semiconductor dies may be positioned directly beneath the impingement cooling block 103. The first, second, third, and fourth semiconductor dies 104, 402, 404, and 406 are system on chip (SoC) dies. The second, third, and fourth semiconductor die 402, 404, 406 respectively have second, third, and fourth active regions 403, 405, 407. As shown in the top down view 400b of FIG. 4B, in some embodiments, with four active regions 105, there are the first region 202, the third region 302, and the fourth region 304, and a fifth region 408 with a higher volume per unit area of impingement openings 120 than the second region 204. As the impingement cooling block 103 is spaced from the one or more semiconductor dies (e.g., the first semiconductor die 104, the second semiconductor die 402, etc.), the impingement cooling block may be used to cool a plurality of semiconductor dies with any combination of active regions in the same way that it would cool a single semiconductor die (e.g., the first semiconductor die 104) with one or more active regions 105.

As shown in the top down view 400c of FIG. 4C, in some embodiments, a plurality of high bandwidth memory (HBM) chips 410 are directly beneath the impingement cooling block 103. The HBM chips 410 are coupled to the first, second, third, and fourth semiconductor dies 104, 402, 404, 406 to expand upon their functionality. As shown in the top down view 400d of FIG. 4D, in some embodiments, with four active regions 105, there are the first region 202, the third region 302, and the fourth region 304, and a fifth region 408 with a higher volume per unit area of impingement openings 120 than the second region 204. Further, one or more impingement openings 120 are also directly above the plurality of HBM chips 410.

As shown in the cross-sectional view 400e of FIG. 4E, in some embodiments, the impingement cooling block 103 overlies a 2.5 dimensional or three dimensional stacked circuit structure. In some embodiments, the circuit structure comprises a combination of one or more semiconductor dies (e.g., the first, second, and third semiconductor die 104, 402, 404, the HBM chip 410) vertically and/or horizontally spaced from one another, where the one or more semiconductor dies are coupled using conductive bumps 412 to one another, the substrate 109, or an underlying interposer 414. In some embodiments, the thermal interface material 106 separates the one or more semiconductor dies from the impingement cooling block 103. In other embodiments, one or more additional fill layers separate the thermal interface material 106 from the one or more dies.

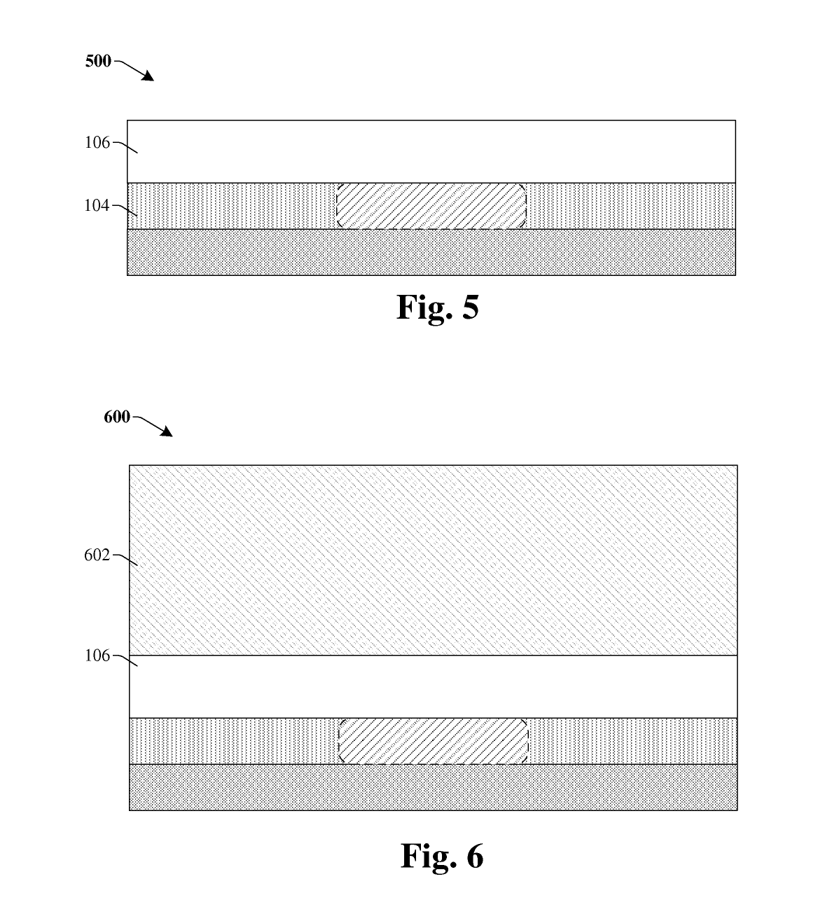

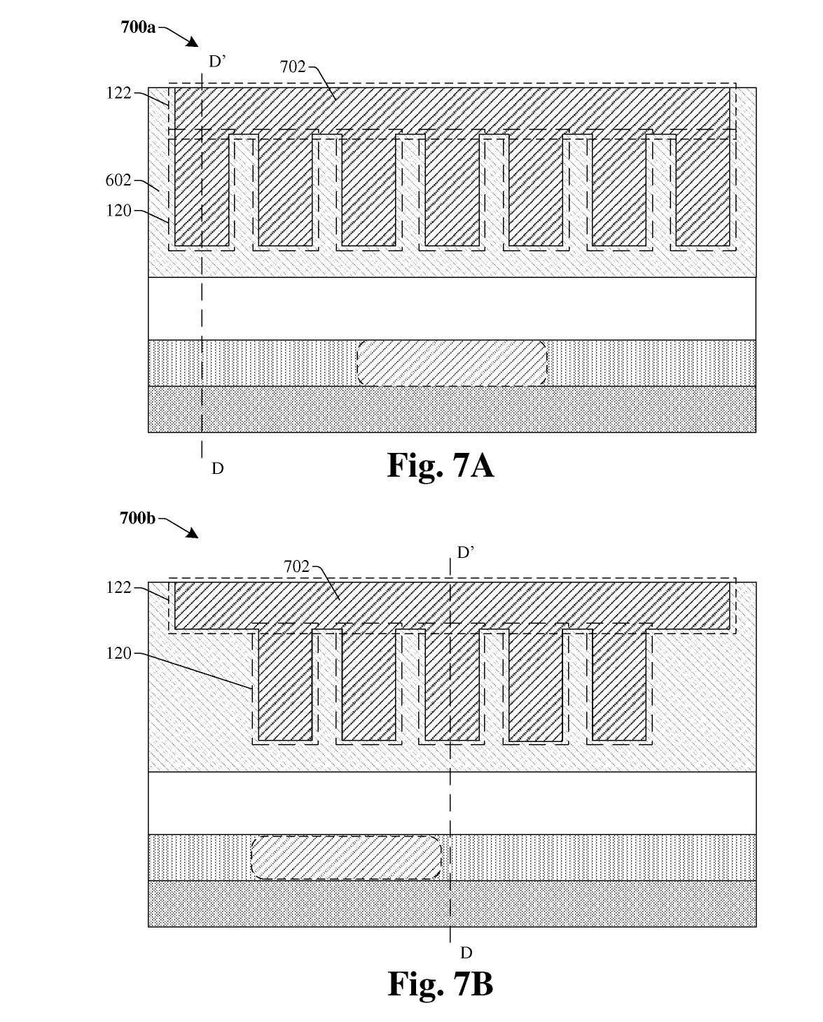

FIGS. 5, 6, 7A, 7B, 8-12, 13A, 13B, 14A, and 14B illustrate a series of cross-sectional views 500, 600, 700a, 700b, 800-1200, 1300a, 1300b, 1400a, and 1400b of some embodiments of a method of forming a liquid cooling system with a plurality of openings directing a coolant at specific regions of a semiconductor die using a plurality of valves. Although FIGS. 5, 6, 7A, 7B, 8-12, 13A, 13B, 14A, and 14B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. The cross-sectional views 700b, 1300b, and 1400bof FIGS. 7B, 13B, and 14B are taken along lines D-D’ of FIGS. 7A, 13A, and 14A respectively.

As shown in the cross-sectional view 500 of FIG. 5, the thermal interface material 106 is formed over the first semiconductor die 104. In some embodiments, the thermal interface material 106 is or comprises a metal, a liquid metal, a polymer gel, a phase change material, a graphite film, or the like. The thermal interface material 106 is formed using one or more of a physical vapor deposition (PVD), atomic layer deposition (ALD), chemical vapor deposition (CVD), a dispensing process (e.g., dispensing a polymer-based material of the thermal interface material), a curing process (e.g., curing a polymer-based material after it is dispensed onto the first semiconductor die), a pick and place process (e.g., a graphite film is positioned on the first semiconductor die), or the like.

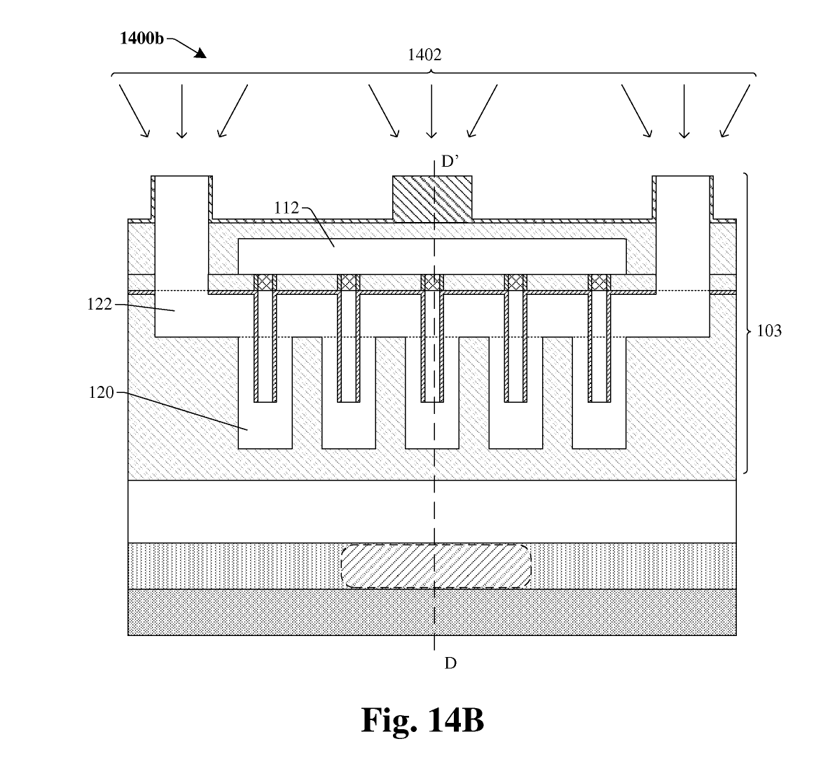

As shown in the cross-sectional view 600 of FIG. 6, a coolant block base 602 is formed on the thermal interface material 106. In some embodiments, the coolant block base 602 is or comprises a thermally conductive material, such as a metal (e.g., aluminum, copper, steel), a metal alloy, or the like. The coolant block base 602 is formed using one or more of PVD, ALD, CVD, or the like. In some embodiments, such as when the thermal interface material 106 does not comprise a solid material, the coolant block base 602 is formed on a separate substrate, and the following steps shown in FIGS. 7-14) are performed while the cooling block base is on the substrate. The finished impingement cooling block (see 103 of FIGS. 1A and FIG.14) is then removed from the substrate and coupled to the thermal interface material.

As shown in the cross-sectional views 700a and 700b of FIGS. 7A and 7B, a plurality of etching steps are performed on the coolant block base 602. The plurality of etching steps result in forming the plurality of impingement openings 120 (shown in phantom) and the outlet opening 122 (shown in phantom). In some embodiments, the plurality of etching steps consist of a first etch to form openings that are aligned with the plurality of impingement openings 120, and a second etch that etches the outlet opening 122 and continues to etch the plurality of impingement openings 120. In some embodiments, the plurality of impingement openings 120 and the outlet opening 122 are patterned using a first masking layer and a second masking layer formed via photolithography. In some embodiments, outer sidewalls of the outlet opening 122 extends past outermost sidewalls of the impingement openings 120 (as shown in FIG. 7B). After the plurality of etching steps, the plurality of impingement openings 120 and the outlet opening 122 are filled with a first sacrificial layer 702.

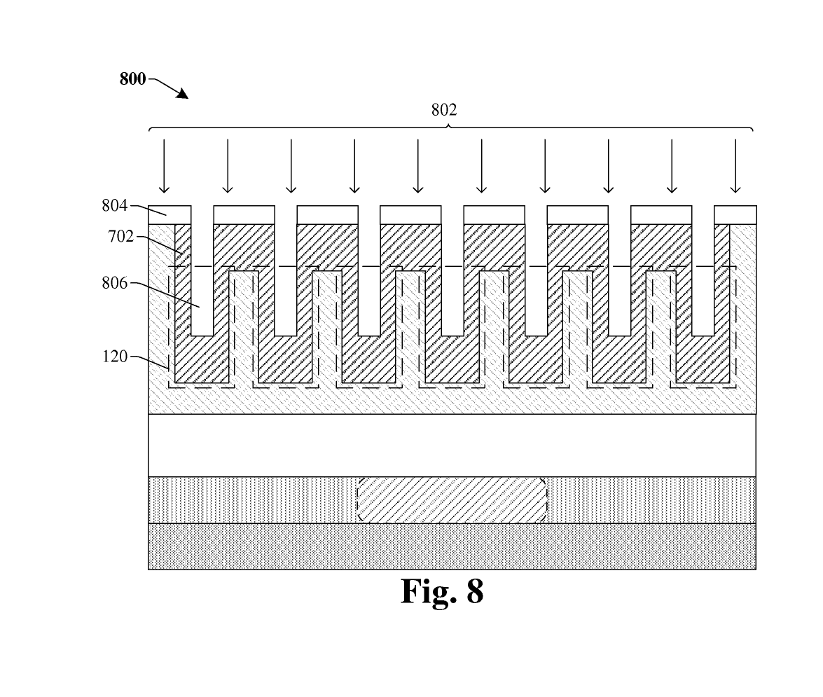

As shown in the cross-sectional view 800 of FIG. 8, a third masking layer 804 is formed over the first sacrificial layer 702 and the coolant block base 602. In some embodiments, the third masking layer 804 is or comprises a photoresist and is patterned using photolithography. The third masking layer 804 is formed using one or more of PVD, ALD, CVD, a spin on process, a dipping process, or the like. After the third masking layer 804 is formed and patterned, a third etch 802 is performed on the first sacrificial layer 702. In some embodiments, the third etch 802 is an anisotropic dry etching process. The third etch 802 results in a plurality of tube openings 806 extending into the plurality of impingement openings 120 (shown in phantom). In some embodiments, the plurality of tube openings 806 have a circular cross-section when viewed from a top-down perspective.

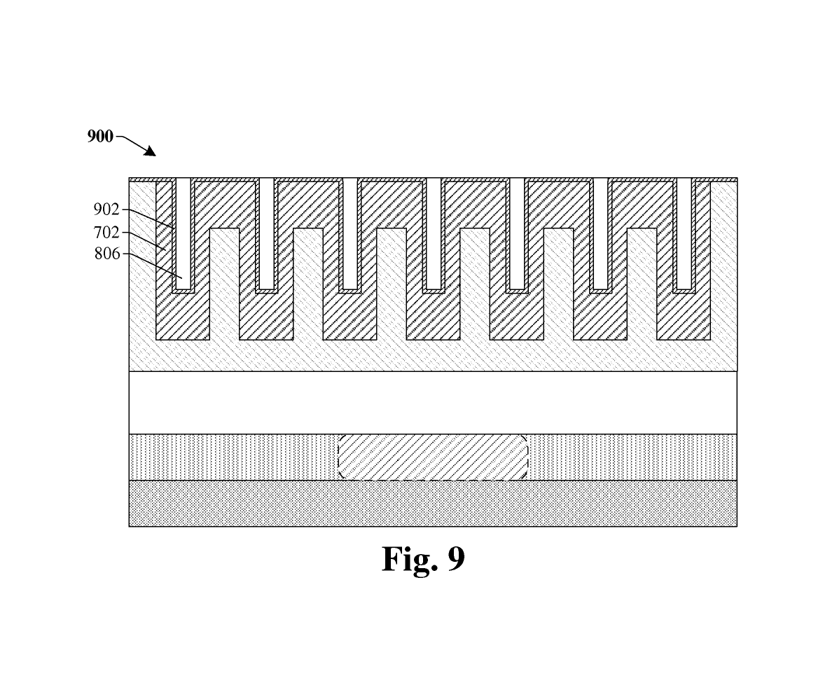

As shown in the cross-sectional view 900 of FIG. 9, a conformal tube layer 902 is deposited over the first sacrificial layer 702 and along sidewalls of the plurality of tube openings 806. In some embodiments, the conformal tube layer 902 is or comprises a same material as the coolant block base 602. In some embodiments, the conformal tube layer is formed using one or more of PVD, ALD, CVD, or the like.

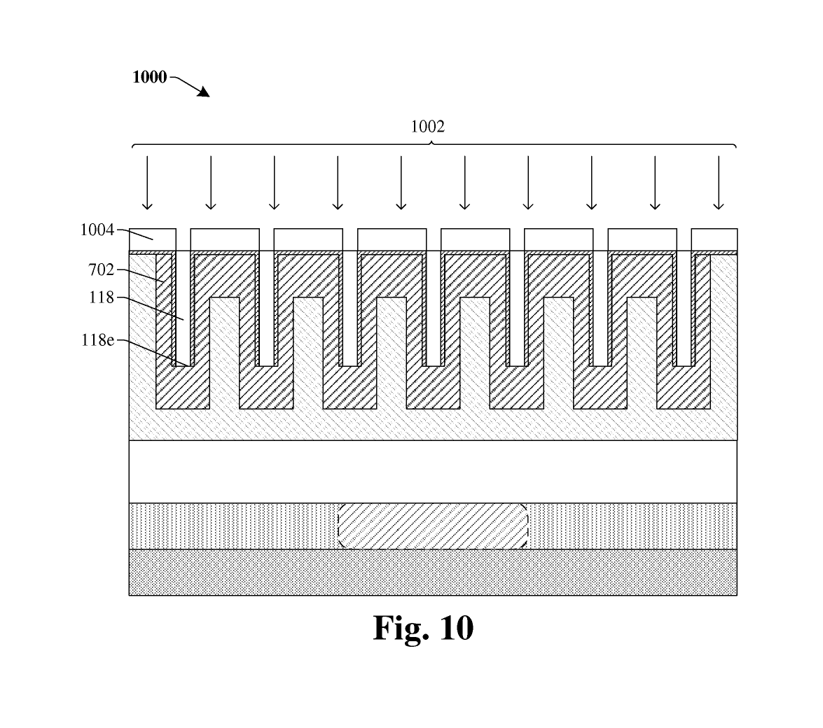

As shown in the cross-sectional view 1000 of FIG. 10, a fourth masking layer 1004 is formed over the conformal tube layer (see 902 of FIG. 9). In some embodiments, the fourth masking layer 1004 is or comprises a photoresist and is patterned using photolithography. The fourth masking layer 1004 is formed using one or more of PVD, ALD, CVD, a spin on process, a dipping process, or the like. After the fourth masking layer 1004 is formed and patterned, a fourth etch 1002 is performed on the conformal tube layer (see 902 of FIG. 9). In some embodiments, the fourth etch 1002 is an anisotropic dry etching process. The fourth etch 1002 results in a portion of the conformal tube layer (see 902 of FIG. 9) at the tube ends 118e of the plurality of tubes 118 being removed.

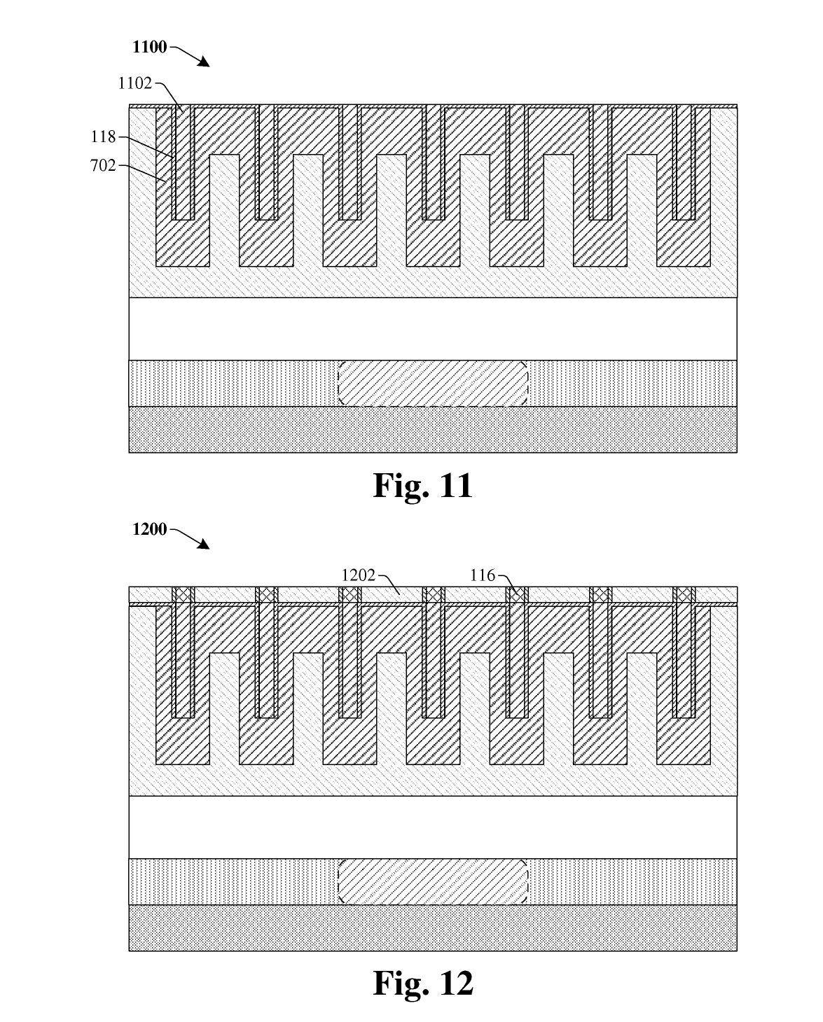

As shown in the cross-sectional view 1100 of FIG. 11, a second sacrificial layer 1102 is formed within the plurality of tubes 118. In some embodiments, the second sacrificial layer 1102 is or comprises a same material as the first sacrificial layer 702. In some embodiments, the second sacrificial layer 1102 is formed by one or more of PVD, ALD, CVD, or the like, followed by a planarization process (e.g., a CMP process or the like) to remove portions of the second sacrificial layer 1102 above an upper surface of the plurality of tubes 118.

As shown in the cross-sectional view 1200 of FIG. 12, the plurality of valves 116 are formed over the plurality of tubes 118. The plurality of valves 116 are surrounded by an intermediate coolant block layer 1202. In some embodiments, the plurality of valves 116 are electromagnetic solenoid valves. In some embodiments, a first wire level (see 123 of FIG. 1B) comprising a plurality of wires is embedded into the intermediate coolant block layer 1202 to couple the plurality of valves 116 to the valve controller (see 127 of FIG. 1B).

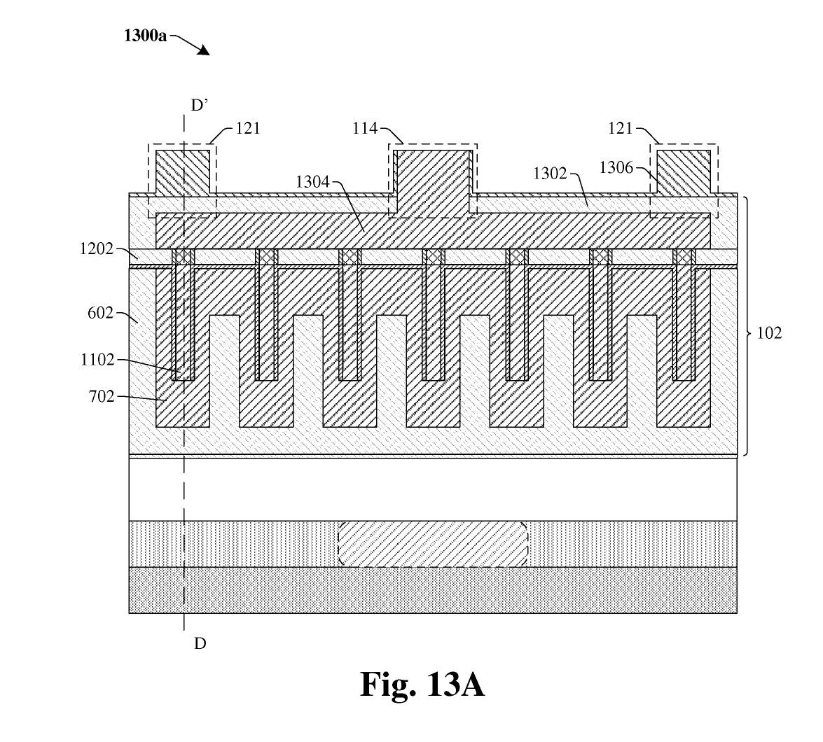

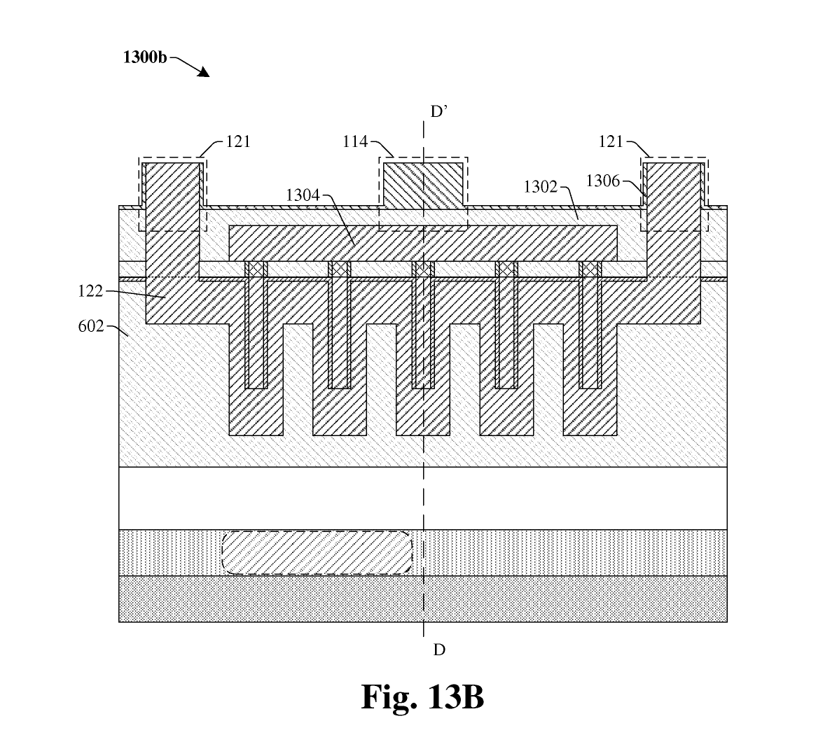

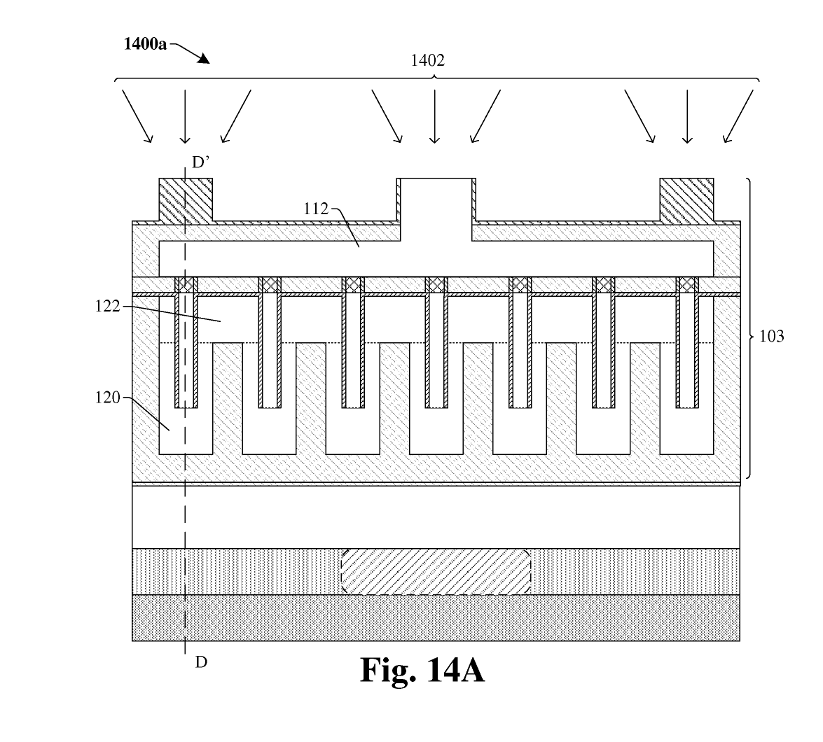

As shown in the cross-sectional views 1300a and 1300b of FIGS. 13A and 13B, a coolant block upper layer 1302 is formed around a third sacrificial layer 1304. The coolant block upper layer 1302, the intermediate coolant block layer 1202, and the coolant block base 602 together form the coolant containment structure 102. Further, sidewalls 1306 of the inlet 114 and the outlets 121 are formed surrounding portions of the third sacrificial layer 1304 corresponding to the inlet 114 and outlets 121, respectively. In some embodiments, a connector is formed at the inlet 114 and the outlets 121 to couple the inlet 114 and outlets 121 to the first coolant line (see 117 if FIG. 1B) and the second coolant lines (see 125 of FIG. 1B), respectively. The coolant block upper layer 1302 and the third sacrificial layer 1304 are formed using a plurality of etching steps and deposition steps. In some embodiments, the third sacrificial layer 1304 comprises a same material as the first sacrificial layer 702 and the second sacrificial layer 1102. In some embodiments, the coolant block upper layer 1302 and the sidewalls 1306 comprise a same material as the coolant block base 602 and are formed in a single deposition step. In other embodiments, multiple separate deposition steps are used to form the coolant block upper layer 1302 and the sidewalls 1306.

As shown in the cross-sectional views 1400a and 1400b of FIGS. 14A and 14B, a fifth etch 1402 is performed on the first, second and third sacrificial layers (see 702, 1102, 1304 of FIGS. 7, 11, and 13, respectively). The fifth etch 1402 is or comprises an isotropic etch that selects for and etches the material of the first, second, and third sacrificial layers. The fifth etch results in the removal of the first, second, and third sacrificial layers (see 702, 1102, 1304 of FIGS. 7, 11, and 13, respectively) from the inlet opening 112, the plurality of impingement openings 120, and the outlet opening 122, completing the impingement cooling block 103.

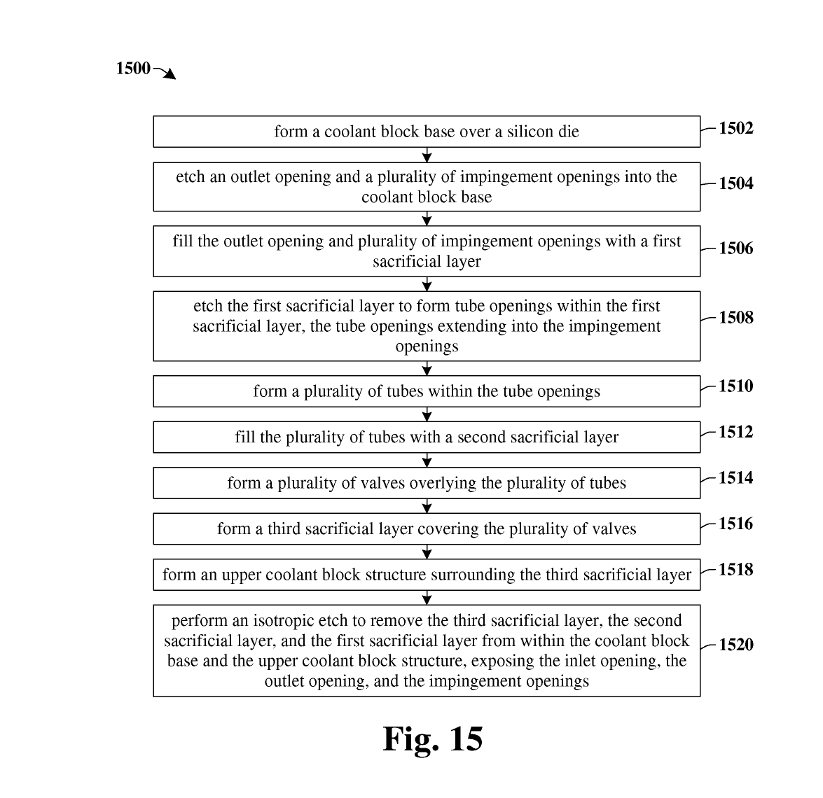

FIG. 15 illustrates a flowchart 1500 of some embodiments of a method of forming a liquid cooling system with a plurality of openings directing a coolant at specific regions of a semiconductor die using a plurality of valves. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1502, a coolant block base is formed over a semiconductor die. An example of a drawing illustrating this step can be found, for example, in FIG. 6.

At 1504, an outlet opening and a plurality of impingement openings are etched into the coolant block base. An example of a drawing illustrating this step can be found, for example, in FIG. 7.

At 1506, the outlet opening and plurality of impingement openings are filled with a first sacrificial layer. An example of a drawing illustrating this step can be found, for example, in FIG. 7.

At 1508, the first sacrificial layer is etched to form tube openings within the first sacrificial layer, the tube openings extending into the impingement openings. An example of a drawing illustrating this step can be found, for example, in FIG. 8.

At 1510, a plurality of tubes are formed within the tube openings. An example of a drawing illustrating this step can be found, for example, in FIGS. 9-10.

At 1512, the plurality of tubes are filled with a second sacrificial layer. An example of a drawing illustrating this step can be found, for example, in FIG. 11.

At 1514, a plurality of valves are formed overlying the plurality of tubes and the second sacrificial layer. An example of a drawing illustrating this step can be found, for example, in FIG. 12.

At 1516, a third sacrificial layer is formed covering the plurality of valves. An example of a drawing illustrating this step can be found, for example, in FIG. 13.

At 1518, an upper coolant block structure is formed and surrounds the third sacrificial layer. An example of a drawing illustrating this step can be found, for example, in FIG. 13.

At 1520, an isotropic etch is performed to remove the third sacrificial layer, the second sacrificial layer, and the first sacrificial layer from within the coolant block base and the upper coolant block structure, removing the filling of the inlet opening, the outlet opening, and the impingement openings. An example of a drawing illustrating this step can be found, for example, in FIG. 14.

Some embodiments relate to an integrated circuit cooling system including: an impingement coolant block overlying a semiconductor die; an inlet opening in the impingement coolant block and coupled to an inlet; a plurality of tubes extending in a first direction directly beneath the inlet opening and having first ends and second ends, where the plurality of tubes are respectively centered on first axes; a plurality of valves coupling the first ends of the plurality of tubes to the inlet opening; a plurality of impingement openings within the impingement coolant block and respectively surrounding the second ends of the second plurality of tubes, where the plurality of impingement openings are respectively centered on the first axes; and an outlet opening within the impingement coolant block and between the inlet opening and the plurality of impingement openings, the outlet opening physically coupling the plurality of impingement openings to an outlet.

Other embodiments relate to an integrated circuit cooling system including: an impingement coolant block overlying a semiconductor die; an inlet opening in the impingement coolant block and coupled to an inlet; a tube extending in a first direction beneath the inlet opening and having a first end and a second end extending between first inner sidewalls, where the first end faces the inlet opening and the second end faces the semiconductor die; an impingement opening within the impingement coolant block, where the impingement opening has second inner sidewalls that surround and are concentric with the first inner sidewalls of the tube; and an outlet opening within the impingement coolant block and between the inlet opening and the impingement opening, where the outlet opening is physically coupling the impingement opening to an outlet.

Yet other embodiments relate to a method of forming an integrated circuit cooling system, including: forming a coolant block base over a semiconductor die; etching an outlet opening and a plurality of impingement openings into the coolant block base; filling the outlet opening and plurality of impingement openings with a first sacrificial layer; etching the first sacrificial layer to form tube openings within the first sacrificial layer, the tube openings extending into the impingement openings; forming a plurality of tubes within the tube openings; filling the plurality of tubes with a second sacrificial layer; forming a plurality of valves overlying the plurality of tubes and the second sacrificial layer; forming a third sacrificial layer covering the plurality of valves; forming an upper coolant block structure surrounding the third sacrificial layer; and performing an isotropic etch to remove the third sacrificial layer, the second sacrificial layer, and the first sacrificial layer from within the coolant block base and the upper coolant block structure, removing the filling of the inlet opening, the outlet opening, and the impingement openings..

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit cooling system comprising:
an impingement coolant block overlying a semiconductor die;
an inlet opening in the impingement coolant block and coupled to an inlet;
a plurality of tubes extending in a first direction directly beneath the inlet opening and having first ends and second ends, wherein the plurality of tubes are respectively centered on first axes;
a plurality of valves coupling the first ends of the plurality of tubes to the inlet opening;
a plurality of impingement openings within the impingement coolant block and respectively surrounding the second ends of the plurality of tubes, wherein the plurality of impingement openings are respectively centered on the first axes; and
an outlet opening within the impingement coolant block and between the inlet opening and the plurality of impingement openings, the outlet opening physically coupling the plurality of impingement openings to an outlet.

2. The integrated circuit cooling system of claim 1, wherein the impingement coolant block has an intermediate coolant block layer separating the inlet opening from the outlet opening, and wherein the intermediate coolant block layer is permeated by the plurality of valves.

3. The integrated circuit cooling system of claim 2, wherein the semiconductor die is separated from the impingement coolant block by a thermal interface material (TIM), and wherein the TIM contacts the semiconductor die and the impingement coolant block.

4. The integrated circuit cooling system of claim 1, wherein outer sidewalls of the outlet opening extend past outer sidewalls of the inlet opening in a second direction perpendicular to the first direction.

5. The integrated circuit cooling system of claim 1, wherein the plurality of tubes and the plurality of impingement openings are distributed in a grid pattern perpendicular to the first direction, such that the plurality of impingement openings are arranged in a plurality of rows and columns that extend across an upper surface of the semiconductor die.

6. The integrated circuit cooling system of claim 1, wherein the semiconductor die comprises a first region containing a higher concentration of high power devices than a second region of the semiconductor die, and wherein the plurality of impingement openings are distributed such that a third region of the impingement coolant block directly over the first region has a greater concentration of impingement openings than a fourth region of the impingement coolant block directly over the second region.

7. The integrated circuit cooling system of claim 6, wherein the semiconductor die comprises a fifth region separated from the first region and containing a higher concentration of high power devices than the second region of the semiconductor die, and wherein the plurality of impingement openings are distributed such that a sixth region of the impingement coolant block directly over the fifth region has a greater concentration of impingement openings than the fourth region.

8. The integrated circuit cooling system of claim 6, further comprising:
a second semiconductor die directly beneath the impingement coolant block, wherein the semiconductor die and the second semiconductor die comprise system on chip (SoC) integrated devices;
wherein the second semiconductor die comprises a fifth region separated from the first region and containing a higher concentration of high power devices than the second region of the semiconductor die, and wherein the plurality of impingement openings are distributed such that a sixth region of the impingement coolant block directly over the fifth region of the second semiconductor die has a greater concentration of impingement openings than the fourth region.

9. The integrated circuit cooling system of claim 8, further comprising:
a high bandwidth memory die directly beneath the impingement coolant block;
wherein the plurality of impingement openings are distributed such that a seventh region of the impingement coolant block directly over the high bandwidth memory die has a greater concentration of impingement openings than the fourth region.

10. The integrated circuit cooling system of claim 1, wherein a first opening of the plurality of impingement openings surrounds a first tube of the plurality of tubes, and wherein inner sidewalls of the first opening are spaced from outer sidewalls of the first tube.

11. An integrated circuit cooling system comprising:
an impingement coolant block overlying a semiconductor die;
an inlet opening in the impingement coolant block and coupled to an inlet;
a tube extending in a first direction beneath the inlet opening and having a first end and a second end extending between first inner sidewalls, wherein the first end faces the inlet opening and the second end faces the semiconductor die;
an impingement opening within the impingement coolant block, wherein the impingement opening has second inner sidewalls that surround and are concentric with the first inner sidewalls of the tube; and
an outlet opening within the impingement coolant block and between the inlet opening and the impingement opening, wherein the outlet opening is physically coupling the impingement opening to an outlet.

12. The integrated circuit cooling system of claim 11, wherein the second inner sidewalls have a circular cross section when viewed from a top-down perspective.

13. The integrated circuit cooling system of claim 11, wherein the second inner sidewalls have a square cross-section when viewed from a top-down perspective.

14. A method of forming an integrated circuit cooling system, comprising:
forming a coolant block base over a semiconductor die;
etching an outlet opening and a plurality of impingement openings into the coolant block base;
filling the outlet opening and plurality of impingement openings with a first sacrificial layer;
etching the first sacrificial layer to form tube openings within the first sacrificial layer, the tube openings extending into the impingement openings;
forming a plurality of tubes within the tube openings;
filling the plurality of tubes with a second sacrificial layer;
forming a plurality of valves overlying the plurality of tubes and the second sacrificial layer;
forming a third sacrificial layer covering the plurality of valves;
forming an upper coolant block structure surrounding the third sacrificial layer; and
performing an isotropic etch to remove the third sacrificial layer, the second sacrificial layer, and the first sacrificial layer from within the coolant block base and the upper coolant block structure, removing the filling of an inlet opening, the outlet opening, and the impingement openings.

15. The method of claim 14, further comprising filling the plurality of tubes with a second sacrificial layer before forming the plurality of valves.

16. The method of claim 14, wherein forming the upper coolant block structure further comprises forming an inlet and outlets within the upper coolant block structure, wherein after the isotropic etch the inlet is coupled to an inlet opening within the upper coolant block structure and overlying the plurality of valves, and the outlets are coupled to the outlet opening.

17. The method of claim 16, wherein the outlet opening extends past outermost sidewalls of the plurality of impingement openings, wherein the outlets are directly over the outlet opening in a first direction, and wherein the outlets are offset from the plurality of impingement openings in a second direction perpendicular to the first direction.

18. The method of claim 14, further comprising:
forming an intermediate coolant block layer before forming the plurality of valves, wherein the plurality of valves are formed within the intermediate coolant block layer.

19. The method of claim 18, wherein forming the intermediate coolant block layer further comprises forming a plurality of wires on the intermediate coolant block layer that are coupled to the plurality of valves.

20. The method of claim 14, wherein the plurality of impingement openings are cylindrical and extend along first axes, and wherein the tube openings are cylindrical and have second axes that coincide with the first axes.
